(19) United States
(12) Patent Application Publication
(10) Pub. No.: US 2008/0030274 A1
(43) Pub. Date: Feb. 7, 2008

(54) Gate Bias Generator

(75) Inventor: Erik Bert Busking, Den Haag (NL)

Correspondence Address: LEYDIG VOIT & MAYER, LTD, TWO PRUDENTIAL PLAZA, SUITE 4900, 180 NORTH STETSON AVENUE, CHICAGO, IL, 60601-6731, US

(73) Assignee: Nederlandse Organisatie voor toegepast-natuurwetenschappelijk Onderzoek TNO, Delft (NL)

(21) Appl. No.: 11/576,036

(22) PCT Filed: Sep. 27, 2005
(86) PCT No.: PCT/NL05/00698

§ 371 Date: Oct. 12, 2007

(30) Foreign Application Priority Data
Sep. 27, 2004 (EP) 04077671.8

(51) Int. Cl. H03F 1/30; H03F 3/195

(52) U.S. Cl. 330/277; 330/289; 330/296

(57) ABSTRACT

The problem to be solved is incomplete compensation of threshold voltage spreading in amplifier FETs for example in MMIC's. The problem is solved in a gate bias circuit comprising a first constant current source (I1) connected between the gate of an amplifier FET (T1) and a second voltage source (V2), whereby the gate of the amplifying FET (T1) is terminated with a first resistor (R1) to an electrical ground, further comprising by a second current constant current source (I2) connected between the gate of the FET (T1) and a first voltage source (V1).

### FIELD OF THE INVENTION

The present invention relates to an amplifier circuit and to a circuit for providing a gate bias voltage for an amplifier field effect transistor (FET).

### BACKGROUND

It is known that a FET amplifier, used for example in end stages in Monolithic Microwave Integrated Circuits (MMIC's), can be provided with a gate bias circuit in order to set the drain current at a predefined level. This can be achieved by a gate bias circuit comprising a voltage divider, whereby the gate of the amplifying FET for example is connected to the junction of two resistors placed in series between a first voltage supply and the second voltage supply or ground.

Such a gate bias circuit has many disadvantages as is known today, among which are voltage supply coupling, whereby supply voltage variations influence the gate bias voltage and thereby change the operating drain current of the FET. Also transconductance variations due to temperature variations, production spread due to threshold voltage variations among different wafers or samples on a wafer of semiconductor material from which the amplifier is produced, change the operating drain current of the FET. The threshold voltage is often defined as the lowest gate voltage for the FET to have a drain current, other than leakage current.

Voltage supply decoupling which is an issue with aforementioned circuit, could be achieved by substituting one of the resistors in aforementioned voltage dividers, namely the resistor which is connected to the negative supply, by a current source.

A simplified diagram of such a FET amplifier circuit with biasing is shown in FIG. 1, comprising an amplifying FET T1, an output impedance L1, connected between the drain and a first voltage source V1, an input capacitor C1, a resistor R1 and the current source I1. The gate bias circuit comprises the resistor R1 and the current source I1, connected between the gate of the amplifying FET and a second voltage source V1. The current source I1 provides for a voltage drop across the resistor R1, thereby biasing the FET T1 gate voltage so that the FET T1 has a drain current at a predetermined level.

The drain current of the FET T1 can be modelled with a simplified function of the gate voltage:

I_{d}=k(V_{gs}−Vₜₕ), wherein I_{d} is the drain current, V_{gs} the gate-source voltage, k the transconductance and Vₜₕ the gate-source threshold voltage.

Apart from aforementioned biasing aimed at removing the production spread in Vth, the transconductance of the amplifying FET may need to be corrected. This need arises from the fact that at high drain currents, the mobility of the charges decreases as function of temperature, leading to a decrease in transconductance. This is depicted in FIG. <8> indicating how the steepness of the Ids/Vgs curve decreases.

Summarizing, there are now two problems left in biasing the amplifying FET's:
1 Production spread: FETs from different production wafers or even from the same wafer may have different threshold voltages (Vₜₕ) due to doping variations. This means that at the same gate bias voltage and transconductance k, different FETs may have considerably different drain currents.
2 Temperature effects: when the FET temperature rises, the transconductance k of the FET drops, even if the drain current Ids is maintained.

1) The effects due to production spread due to Vth spread can be resolved by using a second FET as the current source I1, whereby the second FET is connected with its drain and source between the gate of the amplifying FET and the second voltage source and whereby the gate is adjusted at a reference voltage. This is depicted in FIG. 9. At small Vₜₕ values, the current of the amplifying FET is low, the current of the first current source FET is also proportionally low, having the effect that the gate bias voltage of the amplifying FET increases, becoming less negative, thereby increasing the current of the amplifying FET. The first current source FET, with properly dimensioned resistors, can thus be shown to partially compensate current spread due to production spread.

It may be appreciated that any such compensation of production spread can only take place by integrating the first current source FET on the same chip, or MMIC, with the amplifying FET.

Associated prior art of Vth compensation.

An example of a circuit with an amplifying FET and a gate bias circuit using a first current source FET as current source is disclosed in European patent EP0625822 B1.

A problem associated with this and other known gate bias circuits however is that threshold voltage Vth variations due to production spreading are not compensated in a controlled way.

2) Transconductance variation by temperature and production spread other than Vth spread.

When the amplifying FET depicted in FIG. 1 has a high or low gain due to wafer or chip doping variation, or varying temperature, the first current source FET will have the same gain variation, i.e. high or low gain. Similar to the Vth compensation, the high or low gain of the amplifying FET is compensated to an extent by a decreased or increased gate bias voltage respectively.

Associated Prior Art of Temperature Compensation

The article X-band MMIC Power Amplifier with an On-chip Temperature Compensation Circuit, by Yamauchi et al. uses a reference voltage source and diodes to bias an amplifying FET.

The circuit is impractical because it requires adjustment of a voltage source.

Because both of the above referenced circuits do not fulfill requirements for either full Vth compensation or combined Vth compensation and transconductance compensation, improved realizations are sought.

### SUMMARY OF THE INVENTION

Among others, it is an object of the invention to provide for a gate bias circuit that provides improved compensation for temperature and/or threshold voltage variations.

This object is achieved with a gate bias circuit comprising a first constant current source connected between the gate of an amplifier FET and a second voltage source, wherein the gate of the amplifying FET is terminated with a first resistor to an electrical ground, characterised by a second current constant current source connected between the gate of the FET and a first voltage source.

This circuit has the advantage that deficiencies in the first current source may be fully corrected by the second current source.

The FETS in the disclosed gate bias circuit may be N-FET's, whereby the first voltage source has a positive voltage and the second voltage source has a negative voltage with respect to ground.

A person skilled in the art will know that the teaching of the invention will apply to P-FETs as well with the polarities of the power supply voltages reversed.

In an embodiment the first constant current source comprises a second FET of which the drain is connected to the gate of the amplifying FET and of which the gate-source voltage is held at a constant value allows flexible adjustment of the amplifier FET drain current whilst maintaining full Vth spreading compensation due to production spreading.

In a further embodiment the second constant current source comprises a third FET, of which the source is connected to the gate of the first FET and of which the drain is connected to the first voltage source allows integration on a single chip of the amplifier FET and the gate bias circuit.

Another embodiment, further comprises a fourth resistor and a diode, whereby the resistor is connected between the positive voltage supply and the gate of the third FET and the diode is connected between the gate of the third FET and the gate of the amplifying FET, allows for temperature compensation with he same circuit as production spreading compensation.

### BRIEF DESCRIPTION OF THE DRAWINGS

FIG. 1 shows a basic circuit diagram of an amplifying FET with a gate bias circuit using a current source according to the state of the art.

FIG. 2 shows a basic circuit diagram of an amplifying FET with a generalised gate bias circuit using a FET as the current source according to the state of the art.

FIG. 3 shows a FET amplifier having a gate bias circuit having two current sources according to the invention.

FIG. 4 shows a FET amplifier having a gate bias circuit according to a first embodiment of the invention using an ideal current source.

FIG. 5 shows a FET amplifier having a gate bias circuit according to a preferred embodiment of the invention.

FIG. 6 shows a FET amplifier having a gate bias circuit according to a preferred embodiment of the invention also having temperature compensation.

FIG. 7 shows linearization model of the drain current vs gate-source voltage of a FET.

FIG. 8 shows the effect of temperature on the Id−Vgs curve or a FET.

FIG. 9 shows the effect of Vth spreading due to production spreading on the Id−Vgs curve or a FET.

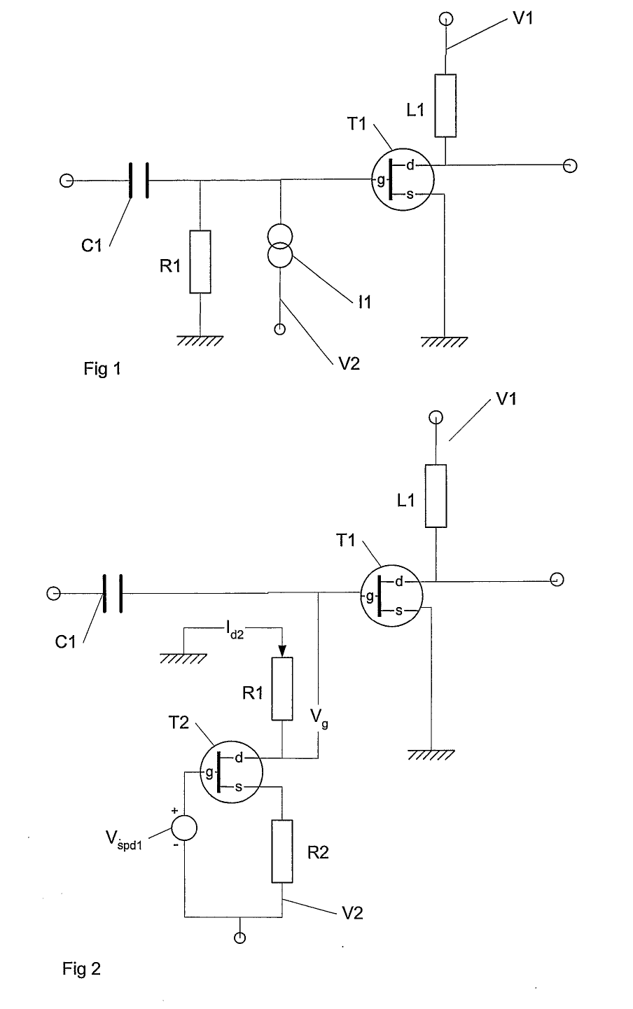

### DETAILED DESCRIPTION

FIG. 2 shows an amplifier circuit with a basic gate bias circuit. The amplifier circuit comprises an amplifier transistor T1 with a gate g, a drain d and source s. Gate g is connected to an amplifier input via a decoupling capacitor C1. Drain d is coupled to a first power supply connection V1 via a load impedance L1. Drain d forms the output terminal of the amplifier circuit. Source s is coupled to ground.

A gate bias circuit is provided that comprises a first resistance R1, a bias transistor T2, a second resistance R2 and a voltage source circuit Vspd1. Bias transistor T2 has a source s coupled to a second power supply connection V2 via second resistance R2. Second power supply connection V2 has a polarity relative to ground opposite to that of first power supply connection V1. In the case of N-type transistors T1, T2 V1 is positive and V2 is negative; in case of P type transistors this is the other way around. Bias transistor T2 has a gate g coupled to second power supply connection V2 via voltage source circuit Vspd1. Bias transistor T2 has a drain d coupled to the gate g of amplifier transistor T1. Preferably the coupling between the drain d of the bias transistor T2 and the gate g of amplifier transistor T1 comprises a high frequency blocking circuit (not shown), so that high frequency signals from decoupling capacitor C1 can reach the gate g of amplifier transistor T1 but not the drain d of the bias transistor T2 (and preferably also not resistance R1). Because amplifier FET T1 has a high DC gate impedance the DC impedance of the coupling to the gate of amplifier transistor T1 is not material. The node between the drain d of bias transistor T2 and the gate g of amplifier transistor T1 is coupled to ground via first resistance R1.

In operation the gate bias circuit serves to compensate for threshold value spread, that is for the fact that the threshold of all (batches of) manufactured transistors is not exactly the same, so that amplifier transistor T1 may have different threshold values in different instances of the circuit. Threshold value spread is counteracted by using a amplifier and bias transistors T1, T2 of a similar conductivity type, with correlated threshold value spread, for example because both transistors are manufactured on a same substrate or from the same production batch.

If the threshold values of amplifier and bias transistors T1, T2 are higher than in an average circuit this means that bias transistor T2 will conduct less drain-source current than in the average circuit, with the result that the voltage drop over first resistance R1 is smaller than average. This raises the gate voltage of amplifier transistor T1 to higher than average, compensating for the higher than average threshold voltage. By adjusting the resistance values of resistances R1 and R2 to appropriate values a range of degrees of compensation for threshold voltage spread can be realized (but not any degree of compensation). Appropriate resistance values may be selected by means of simulation or using mathematical techniques, examples of which will be described in the following.

The circuit of FIG. 2 compensates for some spread in the threshold voltage, but in many cases it is desired to add an offset to the generated gate bias voltage for amplifier transistor T1. This can be realized for example connecting first resistance to a connection other than ground, or by replacing first resistance by a voltage divider (e.g. a pair of resistances) coupled between first power supply connection V1 and ground, the voltage divider having an output coupled to the drain of bias transistor T2 and the gate of amplifier transistor T1.

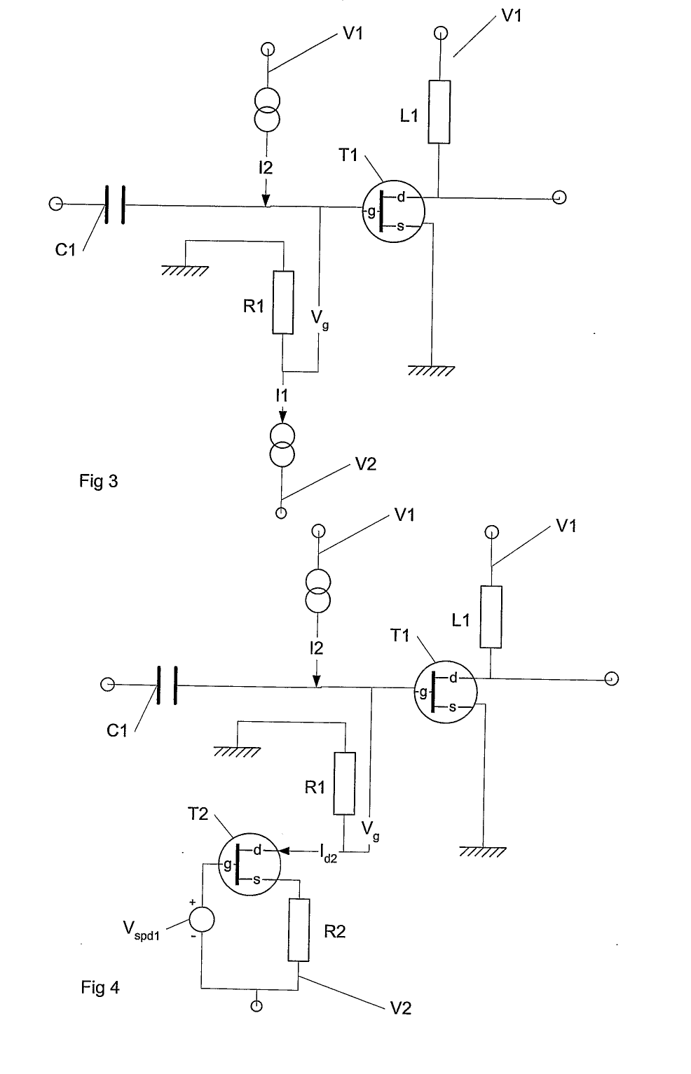

FIGS. 3-6 show further circuits for adding an offset to the generated gate bias voltage for amplifier transistor T1. FIG. 3 shows a principle wherein a first current source of a current I2 is coupled between the first power supply connection V1 and the node between the drain of bias transistor T2 and first resistance R1. A second current source for a current I1 is shown. In FIG. 4 this second current source corresponds to the bias circuit of FIG. 2.

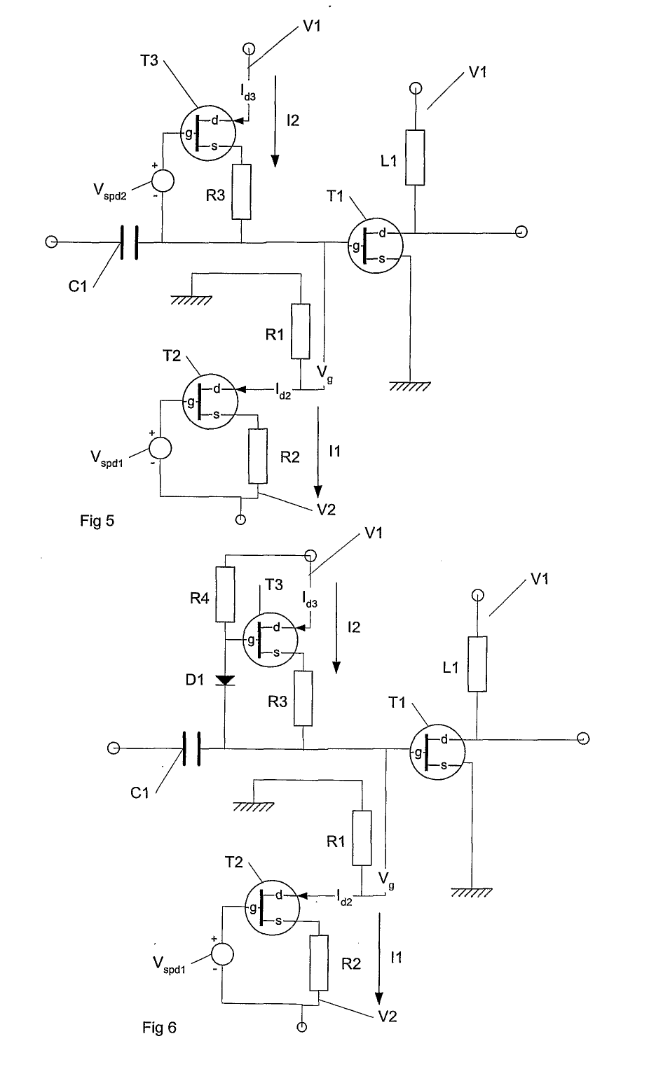

In FIG. 5 the first current source is implemented using a further bias transistor T3, a further current source circuit Vspd2 and a third resistance R3. Further bias transistor T3 has a drain coupled to first power supply connection V1 and a source coupled to the gate of amplifier transistor T1 via third resistance R3. Further bias transistor T3 has a gate coupled to the gate of amplifier transistor T1 via further voltage source circuit Vspd2. Further bias transistor T3 is of the same conductivity type as amplifier transistor T1 and bias transistor T2 and is selected so that its threshold voltage spread correlates with that of amplifier transistor T1 and bias transistor T2. Preferably the coupling between the source s of the further bias transistor T3 and the gate g of amplifier transistor T1 comprises a high frequency blocking circuit (not shown), for example the same blocking circuit that HF blocks bias transistor T2 so that high frequency signals from decoupling capacitor C1 can reach the gate g of amplifier transistor T1 but not the source s of the further bias transistor T3 (and preferably also not resistance voltage source circuit Vspd2).

In operation further bias transistor T3 counteracts threshold voltage compensation by the bias circuit with bias transistor T2. If the threshold values of amplifier and bias transistors T1, T2, T3 are higher than in an average circuit this means that further bias transistor T3 will conduct less drain-source current than in the average circuit, which has a lowering effect on the gate voltage of amplifier transistor T1, aggravating for the higher than average threshold voltage. Therefore, the further bias circuit by itself is not desirable. But in combination with the bias circuit of bias transistor T2 use of the further bias circuit provides for an additional degree of freedom, which allows for adjustment of the gate voltage of amplifier transistor, while maintaining a desired degree of compensation for threshold voltage spread. In general the currents I1 and I2 through the two bias circuits may be approximated by
I1=G1(Vspd1−Va) and I2=G2(Vspd2−Va)

Herein Va is related to the threshold voltage of bias transistors T2, T3 (and correlated to the threshold voltage of amplifier transistor T1. G1 and G2 depend on the properties of bias transistors T2, T3 and the values of resistances R2, R3. The gate voltage of amplifier transistor T1 is
Vg=R1*(I2−I1)
Complete compensation for threshold spread is achieved when
(G2−G1)*R1=1
In this case the gate voltage of amplifier transistor T1 is
Vg=Va+R1*(G2*Vspd2−G1*Vspd1)

If it is desired to design the circuit so that amplifier transistor T1 is biased to a predetermined value of Vg−Va this can be realized with full threshold voltage spread compensation by selecting G1. The selected value of G1 can be realized by means of an appropriate choice of the resistance value of R2. From the selected value of G1 the value of G2 follows. This value may be set by an appropriate choice of the resistance value of R1.

An expression for deriving G2 given the predetermined value of Vg−Va is
R1G2=(Vg−Va+Vspd1)/(Vspd2−Vspd1)

From this it can be seen that for free adjustability of Vg−Va it is desirable that Vspd1 is not equal to Vspd2. Moreover, in most practical circuits it desirable that Vg−Va+Vspd1>0. Hence it is also desirable that Vspd2>Vspd1, that is, that the voltage reference circuit of the bias circuit that is coupled to the positive power supply connection is greater than that of the bias circuit that is coupled to the negative power supply connection, in the case of N-type transistors.

In some circuits it may be desirable to undercompensate or overcompensate for threshold voltage variations. This can be described by a compensation factor A, which is 1 in the case of full compensation of threshold spread, 0.5 in the case of half compensation of spread etc. In this case the condition on G1 and G2 is that
(G2−G1)*R1=A
In this case the gate voltage of amplifier transistor T1 is
Vg=A*Va+R1*(G2*Vspd2−G1*Vspd1)
An expression for deriving G2 given the predetermined value of Vg−Va is now
R1G2=(Vg−A*(Va−Vspd1))/(Vspd2−Vspd1)

As can be seen in this case it is also desirable to set Vspd2>Vspd1 in the case of N-type transistors.

FIG. 6 shows an embodiment wherein a voltage source circuit Vspd2 has been implemented as a forward biased diode. A conventional junction diode may be used, but alternatively a diode-connected further FET (not shown) may be used. Also series arrangements of diodes may be used. Alternative implementations of one or more of the voltage sources include a Zener diode, a voltage divider or any known type of voltage reference circuit. Different Vspd1 and Vspd2 values can be realized for example by using fewer or more diodes in series, different voltage divider circuits etc.

FIG. 2 shows a basic circuit diagram of an amplifying FET with a generalised gate bias circuit using a FET as the current source. As will be demonstrated below it may be difficult to obtain full compensation with this circuit. The drain current I_{d2} through FET T2 can be approximated in a linear approximation:
I_{d2}=k₁(V_{gs2}−Vₐ),
wherein V_{gs2} is the gate-source voltage of FET T2, and Vₐ is the linearised cut-off voltage of FET T2.

The gate-source voltage of FET T2 can be expressed as follows:
V_{gs2}=V_{spd1}−I_{d2}*R2,
wherein V_{spd1}, which will also be referred to as Vr, is a gate reference voltage for FET T2. A person skilled in the art will know that there are various ways to implement a reference voltage, e.g. by using a voltage divider.

Hence the gate bias voltage Vg of FET T1 can be expressed as:

$${V}_{g} = - {I}_{d 2} * R 1 = \frac{- kR 1 * ( {V}_{r} - {V}_{a} )}{1 + kR 2}$$

Va is derived from Vth, the FET threshold voltage. It is assumed that a difference in Vth due to production spreading results in the same difference in Va. Hence:

$$Δ {V}_{g} \approx \frac{kR 1}{1 + k R 2} * Δ {V}_{th}$$

In order to achieve full production spreading compensation for Vth, ΔVg has to be equal to ΔVth. So:

$$\frac{kR 1}{1 + kR 2} = 1 ⟶ R 1 = \frac{1}{k} + R 2$$

The consequence of this is that Vg equals Va−Vr. That means that to achieve full production spreading compensation for the FET threshold voltage, the gate bias voltage for the amplifying FET becomes Va−Vr in the linearised model. That means that the amplifying FET may be completely shut off if Vr=0 or almost completely shut off (Vth<Va). Using a reference voltage Vr>0 even worsens the problem.

Accordingly an offset in Vg may be necessary to be able to bias the amplifying FET T1 in an operational range of Id1, the drain current of FET T1. This can be created by injecting a current in the node between the gate of T1 and the drain of T2.

FIG. 3 shows a gate bias circuit, having a current source I1 connected between the gate of FET T1 and the second power supply and a second current source 12 connected between the gate of FET T1 and the first power supply V2. The current source I1 can be embodied according to FIG. 2 as shown in FIG. 4.

In FIG. 4 a bias FET T2 is depicted, connected to the amplifying FET T1. Not all necessary decoupling components as inductors, transmission lines, capacitors, resistors etc. are indicated as would be in a state-of-the-art embodiment of the invention, as it is chosen to only depict the circuit elements which are relevant to the current invention.

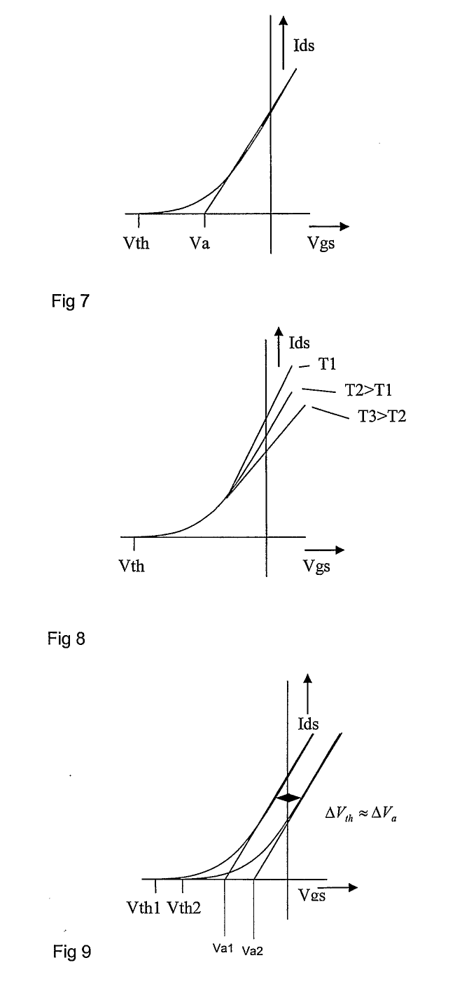

The second current source I2 is assumed to be an ideal current source. V1 is the positive supply (in the order of +5 V), Vn is the negative supply (in the order of −5 V). Va is the voltage representing an abscissa of a FET's linearized Id/Vgs curve, as depicted in FIG. 7.

Since Vth spread, resulting from production spread, substantially involves a horizontal shift of the Id/Vgs curves, the shift of Va substantially equals the shift of Vth, as shown in FIG. 9.

The following derivation may serve to determine resistor values, source and node voltages and currents, for a circuit as depicted in FIG. 4, such values offering both a correct bias voltage and an exact compensation for Vth spread.

$$I 1 = {I}_{d 2} = {k}_{1} ( {V}_{spd 1} - {V}_{a} - {V}_{R 2} ) \& {V}_{R 2} = {I}_{d 2} {R}_{2} -> \\ {I}_{d 2} = {k}_{1} ( {V}_{spd 1} - {V}_{a} - {I}_{d 2} {R}_{2} ) \\ {I}_{d 2} = {k}_{1} {V}_{spd 1} - {k}_{1} {V}_{a} - {k}_{1} {I}_{d 2} {R}_{2} \\ {I}_{d 2} = \frac{{k}_{1} ( {V}_{spd 1} - {V}_{a} )}{1 + {k}_{1} {R}_{2}} \qquad ( 1 )$$

wherein I_{d2} (=I1) is the drain current of FET T2, k₁ is the transconductance of FET T2 and V_{spd1} is the voltage of a first reference source.

The indicated current I_{d2} (=I1) added to a properly chosen current from current source I2 and/or a properly chosen value of V_{spd1}, will yield a voltage drop over R1 leading to the required gate voltage V_{g}, which is needed to bias the Amplifying FET.

$${V}_{g} = {R}_{1} ( - {I}_{d 2} + {I}_{2} ) = - {R}_{1} \frac{{k}_{1} ( {V}_{spd 1} - {V}_{a} )}{1 + {k}_{1} {R}_{2}} + {R}_{1} {I}_{2} \qquad ( 2 )$$

In this embodiment it is the objective to precisely compensate the Vth spread, therefore is calculated:

$$\frac{Δ {V}_{g}}{Δ {V}_{a}} = \frac{{R}_{1} {k}_{2}}{1 + {k}_{1} {R}_{2}} = 1 \qquad ( 3 )$$

Equation (3) yields:

$${R}_{2} = \frac{{R}_{1} {k}_{1} - 1}{{k}_{1}} = R 1 - \frac{1}{{k}_{1}} \qquad ( 4 )$$

### EXAMPLES

Required is a Vg of −0.5 V. Given R1=50 Ohm, K1=40 mA/V, R2=25 Ohm, full compensation is accomplished. However, the DC voltage of Vg, using (1) and assuming V_{spd1}=0 is incorrect:
I_{d2}=k1(V_{spd1}−Va)/(1+k1R2)=40e−3*(0+1)/(1+40e−3*25)=20 mA
Vg=R1*(−I_{d2})=−1 V.

This voltage needs to be raised using another value of V_{spd1} or a current I2, or both).

The value of R2 can become zero if R1k1=0.

The value of R2 calculated in (4), assuming V_{spd1}=0 V and I2=0 mA, generally leads to an incorrect or undesired DC value of Vg.

The correct DC voltage for Vg can be obtained using the following procedure. Substituting R2 in equation (2) by equation (4) yields:

$${V}_{g} = - {R}_{1} \frac{{k}_{1} ( {V}_{spd 1} - {V}_{a} )}{1 + {k}_{1} ( \frac{{R}_{1} {k}_{1} - 1}{{k}_{1}} )} + {R}_{1} {I}_{2} = \frac{- {R}_{1} {k}_{1} ( {V}_{spd 1} - {V}_{a} )}{{R}_{1} {k}_{1}} + {R}_{1} {I}_{2} \\ {V}_{g} = - {V}_{spd 1} + {V}_{a} + {R}_{1} {I}_{2} \qquad ( 5 )$$

Vg is hereafter corrected by (a) modifying I2 or (b) modifying V_{spd1}. The amount is derived below.

(a) Modifying I2

In (5) assume V_{spd1}=0.

$$\begin{matrix}{V}_{g} = {V}_{a} + {R}_{1} {I}_{2} & ( 5 a ) \\ {I}_{2} = \frac{{V}_{g} - {V}_{a}}{{R}_{1}} & ( 6 )\end{matrix}$$

For example:

With required Vg's of

Vg=0 V, Va=−1 V, R1=50 Ohms, I2=20 mA

Vg=−0.5 V, Va=−1 V, R1=50 Ohms, I2=10 mA

Vg=−0.7 V, Va=−1 V, R1=50 Ohms, I2=6 mA

In all these cases the Vth spread remains fully compensated)

(b) Modifying V_{spd1}

In equation (5) assume I2=0.
V_{g}=−V_{spd1}+Vₐ (5b)
V_{spd1}=Vₐ−V_{g} (7)

For example with required Vg values of:

Vg=0 V, Va=−1 V, R1=50 Ohms, V_{spd1}=−1 V

Vg=−0.5 V, Va=−1 V, R1=50 Ohms, V_{spd1}=−0.5 V

Vg=−0.7 V, Va=−1 V, R1=50 Ohms, V_{spd1}=−0.3 V

Also in all these cases the spread remains fully compensated.

In above example, the required values of V_{spd1} are negative, requiring a power supply with a voltage lower than V2, which may in some cases be considered impractical. With FET types possessing less-negative values of Vth and Va, this need can in some cases disappear.

It may be noted that V_{spd1} would in practical cases be realized by means of a voltage divider comprising resistors or a reference element such as a forward conducting diode or zener diode connected to the power supply using a resistor.

Noteworthy is that from above derivations it can be concluded that an over-compensation of Vth spread can be obtained purposely by choosing a value of R2 smaller than calculated in equation (4).

The aforementioned ideal current source 12, connected between R1 and V1 may be embodied using:

a An external stable current source

b A resistor

c A FET current source

Solution a) requires an external connection to the chip, so that any known type of current source may be used which need not be described further.

Solution b) having a resistor R5 between the power supply V1 and the gate of FET T1 as an implementation of the current source.

Using a resistor R5 (not shown) between V1 and R1 or the gate of FET T1 as implementation of current source I2 is a simple means of realizing full Vth compensation and a correct Vg. In fact this resistor and resistance R1 form a current divider.

Using equations (1) . . . (5) describing the case of an ideal current source between Vp and R1, determine R1 for optimal Vth compensation. Next the value of R1 has to be modified. In the dimensioning of R1′ and R5, two equations must be met:

$$\begin{matrix}{R}_{1} = \frac{{R}_{1}^{′} {R}_{5}}{{R}_{1}^{′} + {R}_{5}} & ( 21 ) \\ and & \\ {V}_{g} = {V}_{p} \frac{{R}_{1}^{′}}{{R}_{1}^{′} + {R}_{5}} - {I}_{1} {R}_{1} & ( 22 )\end{matrix}$$

In (21), the parallel arrangement of R1′ and R5 has to have the value of R1 to restore the original Vth spread tracking requirement for Vg (“dynamic”).

In (22) the DC component is represented, to meet the intended Vg (“static”).

Solution c) is shown in FIG. 5. FIG. 5 also comprises a FET current source for 12.

It may be known to the persons skilled in the art, that an ideal current source is not realizable with simple means. In below derivation it is proven that despite utilizing non-ideal current sources, substantially full Vth compensation can be obtained. A circuit possessing two FET current sources is described. This embodiment can be dimensioned to fulfill full Vth spread compensation.

For the top current source I2 can be derived:

$${I}_{2} = {I}_{d 3} = \frac{{k}_{2} ( {V}_{spd 2} - {V}_{a} )}{1 + {k}_{2} {R}_{3}} \qquad ( 11 )$$

For the bottom current source I1 I1 can be derived (see (1)):

$${I}_{1} = {I}_{d 2} = \frac{{k}_{1} ( {V}_{spd 1} - {V}_{a} )}{1 + {k}_{1} {R}_{2}} \qquad ( 12 )$$

The resulting Vg originates from both currents:

$$\begin{matrix}{V}_{g} = {R}_{1} ( {I}_{2} - {I}_{1} ) & ( 13 ) \\ \begin{matrix}{V}_{g} = \frac{{k}_{2} {R}_{1}}{1 + {k}_{2} {R}_{3}} {V}_{spd 2} - \frac{{k}_{1} {R}_{1}}{1 + {k}_{1} {R}_{2}} {V}_{spd 1} + \\ [ \frac{{k}_{1} {R}_{1}}{1 + {k}_{1} {R}_{2}} - \frac{{k}_{2} {R}_{1}}{1 + {k}_{2} {R}_{3}} ] {V}_{a}\end{matrix} & ( 14 )\end{matrix}$$

A special case occurs, when the part in brackets becomes equal to 1:

$$\begin{matrix}[ \frac{{k}_{1} {R}_{1}}{1 + {k}_{1} {R}_{2}} - \frac{{k}_{2} {R}_{1}}{1 + {k}_{2} {R}_{3}} ] = 1 \to & ( 15 ) \\ {V}_{g} = \frac{{k}_{2} {R}_{1}}{1 + {k}_{2} {R}_{3}} {V}_{spd 2} - \frac{{k}_{1} {R}_{1}}{1 + {k}_{1} {R}_{2}} {V}_{spd 1} + {V}_{a} \to & ( 16 ) \\ Δ {V}_{g} = Δ {V}_{a} & ( 17 )\end{matrix}$$

It was shown previously that the Vth shift due to production spread in Va substantially equals the shift in Vth (FIG. 8), yielding:
ΔV_{g}=ΔVₜₕ (18)

It may be understood that any shortcoming in the way the production spread in Va follows the shift in Vth can be corrected for by a slightly deviant choice of components, beneficial to the object of the invention:
ΔV_{g}≈ΔVₜₕ (18a)

When equation (15) is fulfilled, the DC value of Vg can be set modifying only V_{spd1} and V_{spd2}, which within boundaries does not substantially, in its turn, modify the spread compensation.

It may be noted for explanatory reasons leading to a better understanding of the invention that when equation (15) is fulfilled, FET T2 gives an over-compensation and FET T3 gives an undercompensation with opposite sign, of Vth spread, in total yielding the required substantially precise Vth spread compensation.

Examples of possible embodiments of voltage sources V_{spd1} and V_{spd2} are a voltage divider comprising a first and a second member, the first member of which can be any of a resistor a FET or transistor as current source, the second member of which can be any of a resistor, a diode or a zener diode or any voltage reference element.

A preferred embodiment according to the invention has V_{spd1}=0, so the gate of FET T2 is connected to the power supply V2.

For temperature compensation, a temperature sensing element may be used with a temperature sensitive output coupled to the gate of T2 or T3. The sensing element may be a voltage divider between V1 and V2 or V1 and ground etc. for example, with in one branch a temperature dependent resistive element. This could be a FET, diode or temperature dependent resistor or other type of transistor.

At higher temperatures, in FETs a temperature effect occurs at small values of Vg (Vg close to zero). At higher temperature the Id/Vgs slope steepness (transconductance is per definition the Id/Vgs slope) decreases, with two results: The current decreases and the transconductance decreases. The curves are indicated in FIG. 8.

A resulting effect on the amplifying FET T1 is that at high temperature the gain decreases as a result of decreasing transconductance.

The embodiment according to the invention as shown in FIG. 6 establishes temperature compensation in part or in full, using the effect of decreasing transconductance described above.

When R2 is made substantially small or zero, and V_{spd1} is made substantially small or zero, FET T1 is operated in the region in which the curves are affected by temperature as described above. In the extreme case:
R2=0 and
V_{spd1}=0.

It may be noted that in such region of operation of FET T1, the resulting Vth compensation will be larger than with nonzero values of R2 and Vspd1. From above derivation leading to equations (13) to (18) it can be concluded that, in order to provide under-compensation by FET T2, an optimization will be needed with
Vspd2>0,
R3>0.

The result is that FET T2 is not operated in the region where above mentioned temperature effects occur substantially, therefore rendering FET T1 as the main temperature sensing element.

In a promising embodiment of the invention, V_{spd2} is replaced by a divider consisting of a resistor and a diode, FET T1 has an R2=0 and gate connected to its source (V_{spd1}=0).

It may be noted and appreciated, that in optimization of indicated embodiment of the invention, the size of FET T2 and thus transconductance k2 will be larger than of FET T1.

It may be noted and appreciated, that in such optimization, the current through FET T2 will be smaller than in FET T1. As a result of these two settings, FET T2 is operated substantially out of the region of temperature-dependent transconductance as described above, allowing FET T1 to perform non-counteracted temperature compensation.

It may be noted that in optimization of indicated embodiment of the invention two minor disadvantages remain.

a) Temperature effect of Diode

b) Current through diode

c) Diode bias resistor R4

a) Temperature Effect of Diode

The Diode will have a slight temperature effect, to a small degree counteracting the intended temperature compensation. In the overall optimization, this effect can be dealt with by dimensioning the components such that FET 1 performs a slight overcompensation.

B) Current Through Diode

Gives a substantially small Vg offset.

Practically, Id<<I2.

Generally I2 is to be dimensioned substantially small and to be incorporated in I2.

c) Diode Bias Resistor Rd

Gives a substantially small diminishing effect on Vg/Vth tracking.

Practically, R4>>R1.

Generally R4 can be dealt with in dimensioning R1.

It may be appreciated that all descriptions relating to N-channel FETs are also applicable to P-channel FETs, in which case the polarity of all power supplies is considered to be reversed.

1. An amplifier circuit comprising an amplifier FET (T1) a load impedance L1 and a gate bias circuit, the amplifier FET (T1) having a drain coupled to a first power supply connection (V1) via the load impedance (L1), the gate bias circuit comprising a first constant current source (I1) connected between a gate of the amplifier FET (T1) and a second power supply connection (V2), and wherein the gate of the amplifying FET (T1) is terminated with a first resistor (R1) to an electrical reference terminal, and a second current constant current source (I2) is connected between the gate of the FET (T1) and the first power supply connection source (V1).

2. The amplifier circuit according to claim 1, wherein the first constant current source (I1) comprises a bias FET (T2) with a drain coupled to the gate of the amplifying FET (T1), a source coupled to the second power supply connection and a gate coupled to the second power supply connection via a constant voltage source circuit.

3. The amplifier circuit according to claim 1, wherein the second constant current source comprises a further bias FET (T3), of which the source is connected to the gate of the amplifier FET (T1) and of which the drain is connected to the first power supply connection (V1).

4. The amplifier circuit according to claim 3, further comprising a second resistor (R3) coupled between the source of the further bias FET (T3) and the gate of the amplifier FET (T1).

5. The amplifier circuit according to claim 4, further comprising a third resistor (R4) and a diode (D1), wherein the third resistor is connected between the first power supply connection (V1) and the gate of the further bias FET (T3) and the diode (D1) is connected between the gate of the further bias FET (T3) and the gate of the amplifier FET (T1).

6. The amplifier circuit according to claim 1, wherein the first constant current source (I1) comprises a bias FET (T2) with a drain coupled to the gate of the amplifying FET (T1), a source coupled to the second power supply connection and a gate coupled to the second power supply connection via a constant voltage source circuit, the second constant current source comprising a further bias FET (T3), of which the source is connected to the gate of the amplifier FET (T1) of which the drain is connected to the first power supply connection (V1), and of which a gate is coupled to the gate of the amplifier FET (T1) via a further constant voltage source circuit.

7. The amplifier circuit according to claim 1, wherein the voltage source circuit is designed to generate a relatively smaller voltage difference between a gate of a bias transistor (T2) and the second power supply connection than the voltage generated by the further constant voltage source circuit between the gate of the bias transistor (T2) and the gate of the amplifier FET (T1).

8. A gate bias circuit comprising a first constant current source (I1) connected between a gate of an amplifier FET (T1) and a second voltage source (V2), whereby the gate of the amplifying FET (T1) is terminated with a first resistor (R1) to an electrical ground, and wherein a second current constant current source (I2) is connected between the gate of the FET (T1) and a first voltage source (V1).

9. The gate bias circuit according to claim 8, wherein the first constant current source (I1) comprises a second FET (T2) of which the drain is connected to the gate of the amplifying FET (T1) and of which the gate-source voltage is held at a constant value.

10. The gate bias circuit according to claim 8, wherein the second constant current source comprises a third FET (T3), of which the source is connected to the gate of the first FET (T1) and of which the drain is connected to the first voltage source (V1).

11. The gate bias circuit according to claim 10, further comprising a second resistor (R3) connected between the source of the third FET (T3) and the gate of the amplifying FET (T1).

12. The gate bias circuit according to claim 11, further comprising a fourth resistor (R4) and a diode (D1), whereby the resistor is connected between the positive voltage supply (V1) and the gate of the third FET (T3) and the diode (D1) is connected between the gate of the third FET (T3) and the gate of the amplifying FET (T1).

13. The gate bias circuit according to claim 8, wherein the second constant current source (I2) comprises a resistance coupled between the first voltage source (V1) and a drain of a bias FET (T2)

14. The gate bias circuit according to claim 8, further comprising a temperature sensitive element coupled to control the first and/or second current source.

15. The gate bias circuit according to claim 9, wherein the second constant current source comprises a third FET (T3), of which the source is connected to the gate of the first FET (T1) and of which the drain is connected to the first voltage source (V1).

16. The amplifier circuit according to claim 2, wherein the second constant current source comprises a further bias FET (T3), of which the source is connected to the gate of the amplifier FET (T1) and of which the drain is connected to the first power supply connection (V1).
